(19) United States
(12) Patent Application Publication
(10) Pub. No.: US 2017/0233586 A1
(43) Pub. Date: Aug. 17, 2017

(54) SUPER WATER-REPELLENT LAYER STRUCTURE ON WHICH DROPLETS CAN MOVE IN ONE DIRECTION AND METHOD FOR MANUFACTURING SAME

(71) Applicant: Industry-University Cooperation Foundation Hanyang University, Seoul (KR)

(72) Inventors: Dong Rip KIM, Seoul (KR); Kwan-Soo LEE, Seoul (KR); Youngjun CHO, Hwaseong-si (KR); Kyuho LEE, Gunpo-si (KR); Jihyun JUN, Seongnam-si (KR)

(73) Assignee: Industry-University Cooperation Foundation Hanyang University, Seoul (KR)

(21) Appl. No.: 15/323,209

(22) PCT Filed: Dec. 8, 2014
(86) PCT No.: PCT/KR2014/012008

§ 371 Date: Apr. 3, 2017

(30) Foreign Application Priority Data
Jul. 1, 2014 (KR) 10-2014-0081949

(51) Int. Cl. C09D 5/16; C25D 9/12; C23C 16/56; C25D 5/48; C23C 16/40; C09K 3/18; C25D 7/00

(52) U.S. Cl. CPC C09D 5/1681; C09K 3/18; C25D 9/12; C25D 7/006; C25D 5/48; C23C 16/406; C23C 16/56

(57) ABSTRACT

Provided is a super water-repellent layer structure. The super water-repellent layer structure comprises a substrate having a ratchet structure formed on the upper surface thereof and a super water-repellent nanowire structure formed on the ratchet structure, wherein water drops can move in one direction without an external force. A super water-repellent layer structure can be provided which enables water drops to move in one direction using the ratchet structure and the super water-repellent nanowire structure even without force applied from the outside in a state in which the surface thereof is hardly inclined. Thus, such a super water-repellent layer structure can be applied to various industries such as water harvesting, drainage of condensation water of a heat exchanger, etc., a microfluidic industry.

### TECHNICAL FIELD

Example embodiments of the present invention relate in general to a super water-repellent layer structure and more specifically to a super water-repellent layer structure on whose surface droplets can move in one direction without the application of an external force; and a method of manufacturing the same.

### BACKGROUND ART

Recently studied techniques of moving water droplets in one direction that started from simulating nature such as butterfly wings, spider webs, cactus thorn structures, and the like are techniques that have drawn attention in the industry of water harvesting, condensate drainage from heat exchangers or the like, or microfluidics.

However, until now, in moving water droplets in one direction, with a nano- or micro-structure for causing water droplets to move in one direction formed on a material surface, it has been possible to make water droplets roll down in one direction by inclining the surface or applying an external force exerted by a magnetic field, vibration, or the like.

Korean Laid-open Patent Application No. 10-2010-0011213 (Feb. 3, 2010) discloses a method of preparing a material having a superhydrophobic surface and a superhydrophobic material prepared thereby, but there is no disclosed structure that can enable water droplets to move in one direction without the aid of an external force when the surface is hardly inclined.

Therefore, research on such a structure on which water droplets can move in one direction without surface inclination and an external force is needed.

### DETAILED DESCRIPTION OF THE INVENTION

### Technical Problem

To substantially obviate one or more problems of the related art, example embodiments of the present invention provide a super water-repellent layer structure on which water droplets can move in one direction without the aid of an external force, even when the surface of the structure is hardly inclined; and a method of manufacturing the same.

### Technical Solution

In some example embodiments of the present invention, a super water-repellent layer structure on which droplets can move in one direction on a surface thereof includes a substrate having a ratchet structure formed on an upper surface thereof; and a super water-repellent nanowire structure formed on the ratchet structure. The super water-repellent layer structure is capable of enabling water droplets to move in one direction on the substrate thereof without the aid of an external force.

Also, even when the substrate surface is inclined by 5° or less, water droplets may be able to move in one direction on the substrate without the application of an external force.

Moreover, the ratchet structure satisfies conditions in which the absolute value of W₂−W₁ is 50° or more and the height of a constituent triangle of the ratchet structure is 100 μm to 400 μm, wherein W₁ is any one of two angles at the bottom of the constituent triangle of the ratchet structure, and W₂ is the other of the two angles at the bottom of the constituent triangle of the ratchet structure.

Furthermore, the super water-repellent nanowire structure may contain at least one selected from the group consisting of CuO, Cu₂O, CeO₂, and Co₃O₄, and attain a super water-repellent characteristic through the synthesis of a nanowire structure followed by vacuum drying.

In addition, the super water-repellent nanowire structure contains at least one selected from the group consisting of ZnO, TiO₂, Fe₂O₃, Al₂O₃, and SiO₂, and is provided with a water-repellent coating thereon. In this case, the water-repellent coating is prepared using a fluorine-based material or silane-based material.

In other example embodiments of the present invention, a method of manufacturing a super water-repellent layer structure includes a process of preparing a substrate including a ratchet structure formed on an upper surface thereof, and a process of forming a super water-repellent nanowire structure on the ratchet structure, and enables water droplets to move in one direction on a substrate thereof without the application of an external force, even when the substrate surface is inclined by 5° or less.

Also, the ratchet structure satisfies conditions in which the absolute value of W₂−W₁ is 50° or more and the height of a constituent triangle of the ratchet structure is 100 μm to 400 μm, wherein W₁ is any one of two angles at the bottom of the constituent triangle of the ratchet structure, and W₂ is the other of the two angles at the bottom of the constituent triangle of the ratchet structure.

In addition, the process of forming a super water-repellent nanowire structure on the ratchet structure includes forming a nanowire structure on the ratchet structure through hydrothermal synthesis, chemical vapor deposition, or electrochemical deposition; and subsequently forming the super water-repellent nanowire structure by performing vacuum drying or applying a water-repellent coating on the prepared nanowire structure using a fluorine-based material or silane-based material.

### Advantageous Effects of the Invention

According to example embodiments of the present invention, a super water-repellent layer structure that can enable water droplets to move in one direction without the aid of an external force when the surface is hardly inclined can be provided based on the ratchet structure and the super water-repellent nanowire structure.

Such a super water-repellent layer structure provided as thus can be applied to various industries, including the industry of water harvesting, condensate drainage from heat exchangers or the like, and microfluidics.

The technical effects of example embodiments of the present invention are not limited to those mentioned above, and other technical effects not mentioned herein can be clearly understood by those skilled in the art from the following description.

### DESCRIPTION OF THE DRAWINGS

FIG. 1 illustrates a constituent triangle of a ratchet structure.

FIG. 2 illustrates the principle of forces exerted on a water droplet in the ratchet structure.

FIG. 3 is a flowchart for describing a method of manufacturing a super water-repellent layer structure according to an example embodiment of the present invention.

FIG. 4 is a set of diagrams for illustrating an aluminum substrate including a ratchet structure formed on an upper surface thereof.

FIG. 5 is a set of images for illustrating a super water-repellent layer structure according to a manufacturing example.

FIG. 6 is a set of images for showing the measured movement of a water droplet on the super water-repellent layer structure according to the manufacturing example.

FIG. 7 is a set of images for showing the measured movement of a water droplet on a super water-repellent layer structure according to a comparative example.

### MODE OF THE INVENTION

Hereinafter, example embodiments of the present invention will be described in detail with reference to accompanying drawings.

While the present invention may have various modifications and alternative forms, example embodiments of the present invention are shown by way of example drawings and will be hereinafter described in detail. However, the drawings and descriptions are not to limit the present invention to particular forms disclosed herein, but rather, the present invention includes all modifications, equivalents, and substitutions that are consistent with the spirit of the present invention as defined by the claims.

It will be understood that, when an element such as a layer, region, or substrate is referred to as being present “on” another element, the first element may be directly on the second element, or there may be an intervening element present therebetween.

It will be understood that, although the terms such as “first” and “second” may be used to describe various elements, components, regions, layers, and/or parts, the elements, components, regions, layers, and/or parts should not be limited by these terms.

Also, the term “super water-repellent” used in the present invention refers to a water-repellent characteristic that appears as a contact angle of 150° or more and a sliding angle of 10° or less. In this case, the “contact angle” refers to an angle formed between a liquid surface and a solid surface when the stationary liquid surface is in contact with a solid wall. Also, the “sliding angle” refers to an inclination angle, which is measured with respect to a level bottom surface, at which a liquid begins to slide.

Provided below is the description of a super water-repellent layer structure according to an example embodiment of the present invention.

Such a super water-repellent layer structure may include a substrate having a ratchet structure formed on an upper surface thereof; and a super water-repellent nanowire structure formed on the ratchet structure. In this case, water droplets can move in one direction on the substrate without the aid of an external force. Further, even when the substrate surface is inclined by 5° or less (i.e. the surface is hardly inclined), water droplets can move in one direction on the substrate without the application of an external force.

In this case, there is no limit to a material for the substrate, as long as the material can form a ratchet structure on the upper surface.

Also, in this case, the ratchet structure satisfies conditions in which the absolute value of W₂−W₁ is 50° or more and the height of a constituent triangle of the ratchet structure is 100 μm to 400 μm, wherein W₁ is any one of two angles at the bottom of the constituent triangle of the ratchet structure, and W₂ is the other of the two angles at the bottom of the constituent triangle of the ratchet structure.

When the absolute value of W₂−W₁ in the ratchet structure is less than 50°, the force that the ratchet structure applies on a water droplet is weak such that the water droplet may not be able to move in one direction without the application of an external force when the substrate surface is hardly inclined, for example, when the substrate surface is inclined by 5° or less.

The super water-repellent nanowire structure is formed on the ratchet structure. Therefore, when a surface is hardly inclined, the super water-repellent nanowire structure formed on the ratchet structure may enable water droplets to move in one direction without the application of an external force. This is because water droplets are subjected to a force applied in one direction in the ratchet structure, and additionally, the super water-repellent nanowire structure formed on the ratchet structure increases a force by which the surface pushes away the water droplets, thus enabling water droplets to move in one direction without the aid of an external force.

Preferably, the super water-repellent nanowire has a length of 2 μm or more. Also, the super water-repellent nanowire has a tip diameter of 200 nm or less.

In this case, the super water-repellent nanowire structure may contain a material having a water-repellent characteristic. For example, such a material having a water-repellent characteristic may be at least one selected from the group consisting of CuO, Cu₂O, CeO₂ and Co₃O₄. In this case, the super water-repellent nanowire structure may be prepared by first synthesizing a nanowire structure containing such a water-repellent material and then performing vacuum drying to provide a super water-repellent characteristic to the structure.

Also, the super water-repellent nanowire structure may contain at least one selected from the group consisting of ZnO, TiO₂, Fe₂O₃, Al₂O₃, and SiO₂, and attain a super water-repellent characteristic by being provided with a water-repellent coating. In this case, the water-repellent coating may be prepared using a fluorine-based material or silane-based material.

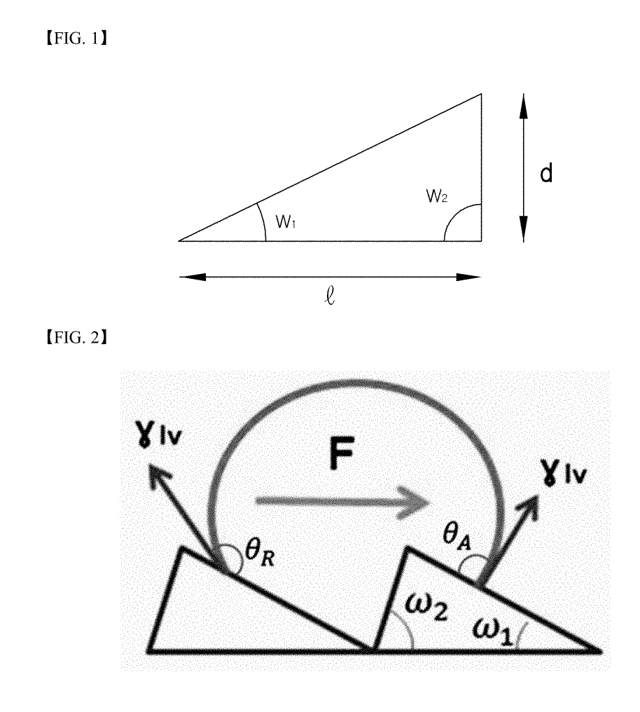

Hereinafter, the ratchet structure and the principle of forces exerted on a water droplet by the ratchet structure will be described with reference to FIGS. 1 and 2.

FIG. 1 illustrates a constituent triangle of a ratchet structure.

Referring to FIG. 1, W₁ is any one of two angles at the bottom of a constituent triangle of the ratchet structure, and W₂ is the other of the two angles at the bottom of the constituent triangle of the ratchet structure.

Also, the constituent triangle of the ratchet structure has a height of “d” and a base length of “l”.

FIG. 2 illustrates the principle of forces exerted on a water droplet in the ratchet structure.

Referring to FIG. 2, when the surface structure is as shown in FIG. 2, a force applied on the water droplet by the surface structure is as described in the below Equation 1:

F=∫_{Left}^{Right}γₗᵥ(cos(θ_{A}+w₁)−cos(θ_{R}+w₂))dl [Equation 1]

θ_{A}, θ_{B}: contact angle between water droplet and surface

γₗᵥ: surface tension of water droplet

As the Equation 1 suggests, the force (F) applied on the water droplet by the surface structure increases as a difference between W₁ and W₂ increases.

Therefore, the formation of a super water-repellent nanostructure on a ratchet structure satisfying conditions in which the absolute value of W₂−W₁ is 50° or more and the height of a constituent triangle of the ratchet structure is 100 μm to 400 μm may enable water droplets to move in one direction without the application of an external force, even when the substrate surface is hardly inclined, for example, when the substrate surface is inclined by 5° or less.

Provided below is a method of manufacturing a super water-repellent layer structure according to an example embodiment of the present invention.

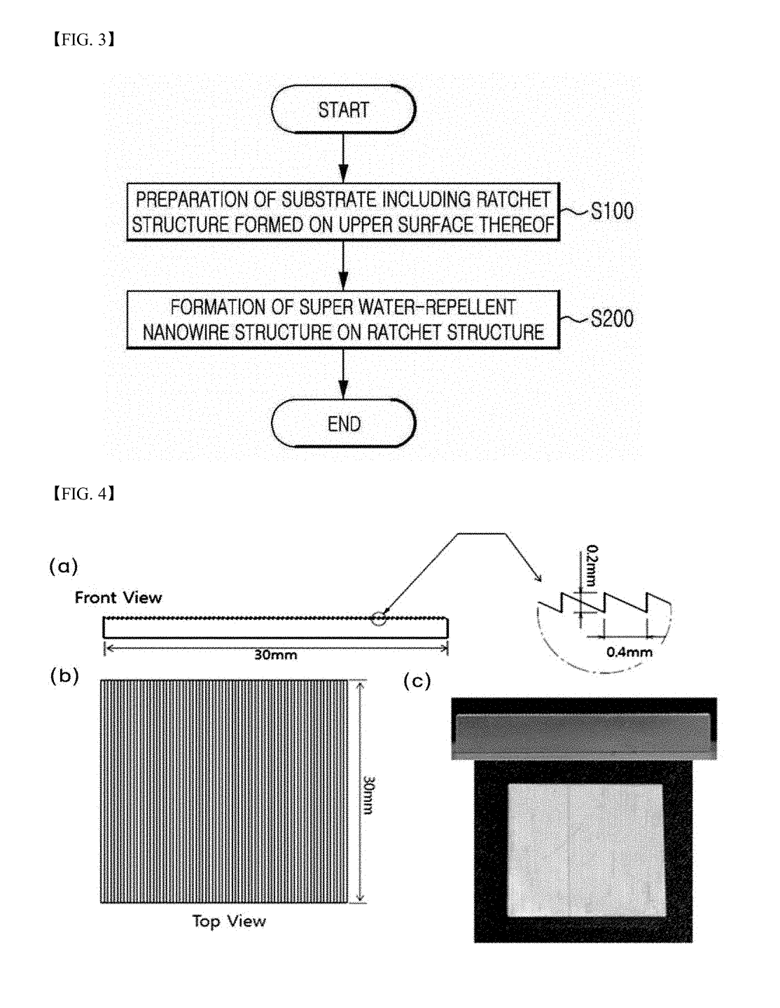

FIG. 3 is a flowchart for describing a method of manufacturing a super water-repellent layer structure according to an example embodiment of the present invention.

Referring to FIG. 3, first, a substrate including a ratchet structure on an upper surface thereof is prepared (S100).

In this case, the ratchet structure satisfies conditions in which the absolute value of W₂−W₁ is 50° or more and the height of a constituent triangle of the ratchet structure is 100 μm to 400 μm. W₁ is any one of two angles at the bottom of the constituent triangle of the ratchet structure, and W₂ is the other of the two angles at the bottom of the constituent triangle of the ratchet structure.

Such a ratchet structure may be formed, for example, through Computerized Numerical Control (CNC) processing.

Next, a super water-repellent nanowire structure is formed on the ratchet structure (S200).

The super water-repellent nanowire structure may be formed in two ways:

First, a process of forming the super water-repellent nanowire structure on the ratchet structure may include forming a nanowire structure on the ratchet structure through hydrothermal synthesis, chemical vapor deposition, or electrochemical deposition; and subsequently forming a super water-repellent nanowire structure by applying a water-repellent coating on the prepared nanowire structure using a fluorine-based material or silane-based material.

Second, the super water-repellent nanowire structure may be formed by vacuum drying a nanowire structure that has been formed on the ratchet structure in the above-described manner.

For example, when an aluminum substrate including a ratchet structure formed on an upper surface thereof is immersed in a mixed solution of a cerium precursor prepared by mixing cerium (III) nitrate hexahydrate (Ce(NO₃)₃. 6H₂O) and urea (CO(NH₂)₂), subjected to hydrothermal synthesis at 95° C. for 24 hours for the growth of cerium oxide nanowires on the ratchet structure, and then dried at 190° C. for one hour in a vacuum, the growth of super water-repellent cerium oxide nanowires may be accomplished.

Therefore, a super water-repellent nanowire structure that is formed on the ratchet structure satisfying specific conditions as described above may enable water droplets to move in one direction without the application of an external force, even when the substrate surface is hardly inclined, for example, when the substrate surface is inclined by 5° or less.

### Manufacturing Example

A super water-repellent layer structure according to an example embodiment of the present invention was manufactured.

First, an aluminum substrate including a ratchet structure on an upper surface thereof was prepared.

FIG. 4 is a set of diagrams for illustrating an aluminum substrate including a ratchet structure formed on an upper surface thereof.

Referring to FIG. 4, any one of two angles at the bottom of a constituent triangle of the ratchet structure (W₁) is about 26.56°, and the other of the two angles at the bottom of the constituent triangle of the ratchet structure (W₂) is about 90°. Therefore, the absolute value of W₂−W₁ is about 64°.

Also, the constituent triangle of the ratchet structure has a height (d) of 0.2 mm and a base length (l) of 0.4 mm.

Next, an aluminum substrate including the ratchet structure was immersed in a mixed solution of a cerium precursor prepared by mixing cobalt nitrate hexahydrate (Co(NO₃)₂. 6H₂O) and urea (CO(NH₂)₂), subjected to hydrothermal synthesis at 95° C. for 12 hours to form a cobalt oxide nanowire structure on the ratchet structure, and then dried at 190° C. for one hour in a vacuum so that a super water-repellent cobalt oxide nanowire structure grew on the ratchet structure.

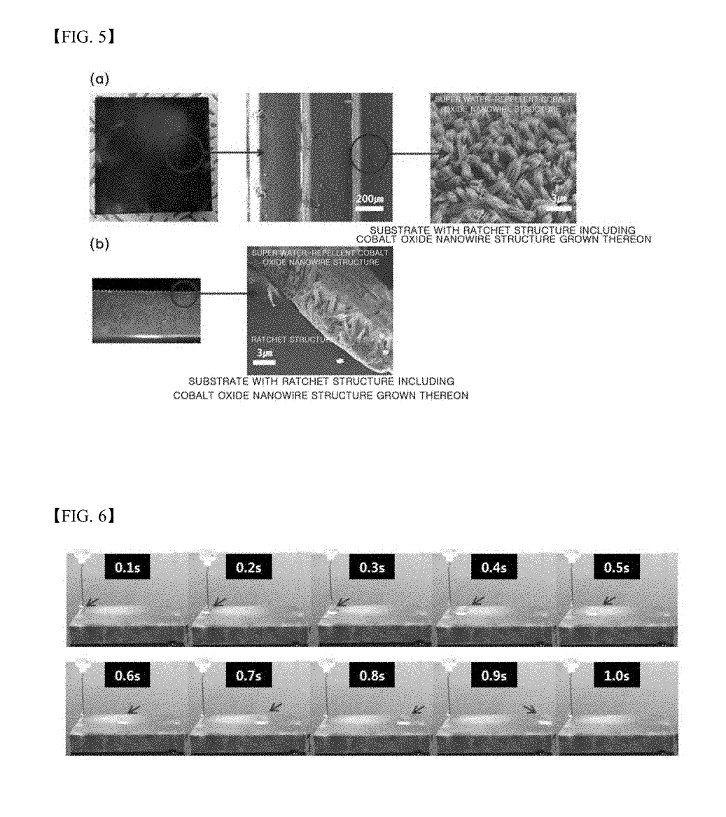

FIG. 5 is a set of images for illustrating a super water-repellent layer structure according to a manufacturing example.

FIG. 5A is a set including an image showing the super water-repellent layer structure according to a manufacturing example from the top and a magnified image thereof. Referring to FIG. 5A, the substrate is viewed from the top, and magnification thereof shows the growth of a cobalt oxide nanowire structure on the ratchet structure.

FIG. 5B, which is a set including an image showing the super water-repellent layer structure according to a manufacturing example from the side and a magnified image thereof, also shows the growth of a cobalt oxide nanowire structure on the ratchet structure.

### Comparative Example

An aluminum substrate including a ratchet structure on an upper surface thereof was prepared.

Any one of two angles at the bottom of a constituent triangle of the ratchet structure (W₁) is about 45°, and the other of the two angles at the bottom of the constituent triangle of the ratchet structure (W₂) is about 90°. Therefore, the absolute value of W₂−W₁ is about 45°.

Also, the constituent triangle of the ratchet structure has a height (d) of 0.2 mm and a base length (l) of 0.2 mm.

Next, a super water-repellent cobalt oxide nanowire structure was formed on the aluminum substrate including such a ratchet structure in the same manner as the above-described manufacturing example.

### Test Example

A 6 μl to 8 μl water droplet was dropped on the super water-repellent layer structures according to the manufacturing example and the comparative example, and the movement of the water droplet in one direction was observed. The movement of the water droplets was observed while the substrate surface was inclined by 5° or less (i.e. the surface is hardly inclined) and no external force was being applied.

FIG. 6 is a set of images for showing the measured movement of a water droplet on a super water-repellent layer structure according to a manufacturing example.

Referring to FIG. 6, when the substrate surface is hardly inclined, the water droplet moves in one direction over time, without the aid of an external force.

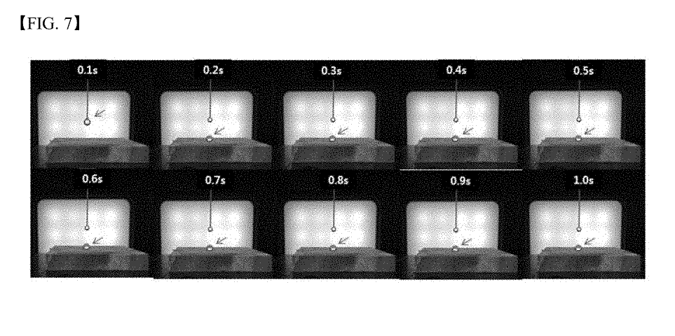

FIG. 7 is a set of images for showing the measured movement of a water droplet on a super water-repellent layer structure according to a comparative example.

Referring to FIG. 7, when the substrate surface is hardly inclined and no external force is applied, the water droplet hardly moves over time.

Therefore, with a super water-repellent nanowire structure formed on the ratchet structure satisfying the above-mentioned conditions of a ratchet structure, water droplets can move in one direction without the application of an external force, even when the substrate surface is inclined by 5° or less (i.e. the substrate surface is hardly inclined).

Meanwhile, the example embodiments of the present invention disclosed in the present specification and drawings are only illustrative of specific examples to help understanding, and are not intended to limit the scope of the present invention. It will be apparent to those skilled in the art that other modifications based on the technical spirit of the present invention are possible in addition to the example embodiments of the present invention disclosed herein.

1. A super water-repellent layer structure, comprising:
a substrate having a ratchet structure formed on an upper surface thereof; and
a super water-repellent nanowire structure formed on the ratchet structure,
wherein water droplets can move in one direction on the substrate without an aid of an external force.

2. The super water-repellent layer structure of claim 1, wherein water droplets can move in one direction on the substrate without an aid of an external force, even when a surface of the substrate is inclined by 5° or less.

3. The super water-repellent layer structure of claim 1, wherein the ratchet structure satisfies conditions in which an absolute value of W₂−W₁ is 50° or more and a height of a constituent triangle of the ratchet structure is 100 μm to 400 μm,
wherein W₁ is any one of two angles at a bottom of the constituent triangle of the ratchet structure, and W₂ is the other of the two angles at the bottom of the constituent triangle of the ratchet structure.

4. The super water-repellent layer structure of claim 1, wherein the super water-repellent nanowire structure contains at least one selected from the group consisting of CuO, Cu₂O, CeO₂, and Co₃O₄, and attains a super water-repellent characteristic through the synthesis of a nanowire structure followed by vacuum drying.

5. The super water-repellent layer structure of claim 1, wherein the super water-repellent nanowire structure contains at least one selected from the group consisting of ZnO, TiO₂, Fe₂O₃, Al₂O₃, and SiO₂, and is provided with a water-repellent coating thereon.

6. The super water-repellent layer structure of claim 5, wherein the water-repellent coating is prepared using a fluorine-based material or silane-based material.

7. A method of manufacturing a super water-repellent layer structure, comprising:
a process of preparing a substrate including a ratchet structure formed on an upper surface thereof; and
a process of forming a super water-repellent nanowire structure on the ratchet structure,
wherein water droplets are able to move in one direction on the substrate without an aid of an external force, even when a surface of the substrate is inclined by 5° or less.

8. The method of claim 7, wherein the ratchet structure satisfies conditions in which an absolute value of W₂−W₁ is 50° or more and a height of a constituent triangle of the ratchet structure is 100 μm to 400 μm, wherein W₁ is any one of two angles at a bottom of the constituent triangle of the ratchet structure, and W₂ is the other of the two angles at the bottom of the constituent triangle of the ratchet structure.

9. The method of claim 7, wherein the process of forming a super water-repellent nanowire structure on the ratchet structure includes:
forming a nanowire structure on the ratchet structure through hydrothermal synthesis, chemical vapor deposition, or electrochemical deposition; and
subsequently forming the super water-repellent nanowire structure by performing vacuum drying or applying, using a fluorine-based material or silane-based material, a water-repellent coating on the nanowire structure that has been prepared above.
